(19) United States
(12) Patent Application Publication
(10) Pub. No.: US 2024/0324107 A1
(43) Pub. Date: Sep. 26, 2024

(54) Debossed Contact Printing as a Patterning Method for Paper-Based Electronics

(71) Applicant: Universtiy of Windsor, Windsor (CA)

(72) Inventors: Tricia Breen Carmichael, Windsor (CA); Sara S. Mechael, Windsor (CA)

(21) Appl. No.: 18/612,296

(22) Filed: Mar. 21, 2024

Related U.S. Application Data
(60) Provisional application No. 63/492,021, filed on Mar. 24, 2023.

(51) Int. Cl. H05K 3/12; H01B 1/12; H05K 1/03; H05K 1/09

(52) U.S. Cl. CPC H05K 3/1241; H01B 1/124; H05K 1/0386; H05K 1/097

(57) ABSTRACT

In a preferred embodiment, there is provided a method for preparing a printed electronic device, the method comprising debossing a recessed relief or relief pattern into a plane of a substrate, and applying an electrically functional ink generally along the plane, thereby depositing the ink on the substrate substantially without depositing the ink on the recessed relief or relief pattern.

The present invention relates to a method for preparing a printed electronic device, and which preferably includes debossing a recessed relief pattern into a plane of a paper substrate and applying an electrically functional ink along the plane to deposit the ink on the substrate and not the recessed relief pattern.

### BACKGROUND OF THE INVENTION

The rapid growth of the internet of things (IoT) is expediting the widespread incorporation of printed electronic devices to collect and communicate data. Examples of printed devices include printed antennas, sensors, and displays for applications in inventory and package tracking, anti-theft and counterfeiting, food quality monitoring, and pharmaceutical dose tracking. The extensive applicability and short lifetime of smart packaging will profoundly accelerate an already mature electronic waste (e-waste) problem. The 2020 Global E-Waste Monitor reported that only 17% of global e-waste disposal is documented, while the remaining 83% is assumed to be improperly disposed, dumped in the environment, or illegally exported. Manufacturers must therefore consider the environmental impact of the components used to fabricate smart packaging to responsibly participate in this market. Research efforts have focused on developing green conductive inks and ink processing alternatives. However, polyethylene terephthalate (PET) has dominated as the substrate of choice for printed electronics because of its smoothness and flexibility, despite its substantial contribution to the weight of a printed device and its environmental persistence. There is a pressing obligation to adopt greener substrates such as paper for disposable printed electronics. Paper offers many advantages for printed electronics: it is sourced from renewable materials, is biodegradable, and has established recycling procedures. Paper is significantly lower cost (˜10 cents/m²) compared to PET (˜2 dollars/m²), it is compatible with high-throughput roll-to-roll (R2R) printing, and can also withstand higher processing temperatures than plastic substrates. However, printing electronically functional inks on paper is challenging because the porosity and hydrophilicity of the entangled cellulose fibers that comprise the microstructure of paper promote wicking, which disperses printed inks into the depth of the paper and leads to poor electrical performance and printing resolution. Despite substantial work to develop paper-based printed electronics, it remains a challenge to pattern functional inks effectively on paper.

Approaches to develop paper-based electronics have included modifying the paper composition itself to create intrinsically conductive paper, planarizing the paper surface with polymer layers to improve printability, or patterning hydrophobic resists on the paper surface to guide ink deposition. Methods to prepare intrinsically conductive paper involve suspending the paper pulp and a conductive filler together and subsequently dehydrating the mixture into a sheet, or soaking an unmodified paper sheet in the conductive filler solution. Typical conductive fillers include carbon-based nanomaterials such as carbon black, graphene, reduced graphene oxide, and carbon nanotubes (CNTs); metal nanomaterials such as silver nanowires (AgNWs) and gold nanoparticles; or conductive polymers such as poly(3,4-ethylenedioxythiophene) polystyrene sulfonate (PEDOT:PSS) and polypyrrol. The composite papers feature a conductive percolation network throughout the cellulose fiber network. However, homogeneously conductive paper is limited to applications that do not require patterning of the electronic elements, such as large area electrodes. While some of these paper composites have been used as interconnects, tensile strain sensors, and electrodes in supercapacitors, their device integration requires cutting and adhering to other device elements. A recently reported example of patternable conductive paper composites used low loading amounts of carbon black fillers to create low-conductivity paper composites that can be selectively activated by pressure to create patterned regions with higher conductivity. While this innovative method is promising for developing patternable paper-based electronics, further work is required to eliminate cross-talk through the low-conductivity regions. Using unmodified paper for printed electronics takes advantage of existing paper products; however, direct printing onto paper requires additional layers to improve the printability of functional inks and minimize ink wicking. Efforts to improve printability have used planarizing hydrophobic coatings such as latex, resin, or polyethylene. Coated paper receives printed silver ink similarly to PET substrates with comparable ink uniformity, printing resolution, and sheet resistance. However, the deposition or lamination of a polymeric hydrophobic layer may compromise the biodegradability and/or recyclability of the paper substrate, and also increase the cost to an extent that may be prohibitive to many disposable smart packaging applications. Another approach reduces the amount of hydrophobic material present by patterning it onto the paper to fill in the pores and act as a resist or barrier for ink wicking, similar to paper-based microfluidic devices that use a printed wax layer to guide the wicking of fluids. Functional inks such as PEDOT:PSS and multi-walled CNTs printed onto the patterned paper wick through the regions of the paper that are uncoated with wax resist to create patterned conductive paper composite traces. However, the wax resist material must be subsequently removed, otherwise its presence may compromise recyclability.

### SUMMARY OF THE INVENTION

It is a non-limiting object of the present invention to provide a method for preparing a printed electronic device, and which may be performed with reduced costs or complexity without necessarily or negatively affecting the device function or performance.

It is another non-limiting object of the present invention to provide a method for preparing a printed electronic device, and which may permit preparation of the printed electronic device with a more recyclable substrate or material with reduced impact on the environment.

In one aspect, the present invention provides a method for preparing a printed electronic device, the method comprising debossing a recessed relief or relief pattern into a plane of a substrate, and applying an electrically functional ink generally along the plane, thereby depositing the ink on the substrate substantially without depositing the ink on the recessed relief or relief pattern.

In another aspect, the present invention provides a method for preparing a printed electronic device, the method comprising providing a substrate having a generally planar substrate surface; debossing a relief or relief pattern into the substrate surface, the relief or relief pattern being recessed from the substrate surface; and applying an electrically functional ink to the substrate surface with a generally cylindrical roller, thereby depositing the ink on the substrate surface substantially without depositing the ink on the relief or relief pattern.

In yet another aspect, the present invention provides a method for preparing a printed electronic device, the method comprising compressing a portion of a paper substrate substantially into a plane thereof to obtain a recessed surface portion and a non-recessed surface portion, and applying an electrically functional ink generally along the plane, thereby depositing the ink on the non-recessed surface portion substantially without depositing the ink on the recessed surface portion, wherein the recessed surface portion is selected to reduce movement of the ink from the non-recessed surface portion.

It is to be appreciated that the substrate is not particularly limited, provided that the substrate permits for compression/debossing and application/deposition of the electrically functional ink. In one embodiment, the substrate comprises paper, cardboard, foamboard, fabric or polymer. In one embodiment, the polymer comprises poly(ethylene terephthalate) (PET), poly(ethylene naphthalate) (PEN), poly(imide) (PI), polyethylene, polypropylene or polyvinyl chloride. In one embodiment, the paper comprises watercolor paper, printing paper, copy paper, cardstock, recycled paper, parchment paper, cotton paper, newsprint, construction paper, tracing paper, glossy paper or filter paper. In one embodiment, the fabric comprises woven, knitted or nonwoven fabric, preferably comprising polyester, cotton, rayon, nylon, velour, velvet, leather, faux leather, faux fur, polyethylene terephthalate or polypropylene. In one embodiment, the substrate comprises paper or watercolor paper having a thickness between about 100 μm and about 1,000 μm, a grammage between about 50 g/m² and about 700 g/m², and/or a water contact angle between about 80° and about 160°. In one embodiment, the thickness is between about 200 μm and about 800 μm, between about 300 μm and about 600 μm, or about 450 μm. In one embodiment, the grammage is between about 100 g/m² and about 500 g/m², between about 200 g/m² and about 400 g/m², or about 300 g/m². In one embodiment, the contact angle is between about 100° and about 140°, between about 110° and about 130°, or about 124°.

In one embodiment, the substrate or paper substrate comprises a collapsible pore structure, whereby the recessed relief, relief pattern or surface portion comprises the pore structure in a collapsed state. In this regard, it has been appreciated that the pore structure in the collapsed state may facilitate reducing or inhibiting ink wicking into, for example, the recessed relief, relief pattern or surface portion. In one embodiment, the method is to be performed with a plurality of the substrate or paper substrate in a stacked or layered arrangement. In one embodiment, the substrate or paper substrate is hydrophobic or comprises a hydrophobic surface, preferably wherein the electrically functional ink is deposited on the hydrophobic surface. In one embodiment, the substrate or paper substrate comprises gelatin, alkyl ketene dimer or alkenyl succinic acid anhydrate selected for reducing water absorbency.

In one embodiment, the recessed relief, relief pattern or surface portion is recessed to a depth between about 10 μm and about 700 μm from the plane or substrate surface, optionally wherein the depth is selected to reduce movement of the ink to the recessed relief, relief pattern or surface portion. In one embodiment, the depth is between about 20 μm and about 500 μm, between about 30 μm and about 300 μm, between about 40 μm and about 100 μm, or about 100 μm. In one embodiment, the recessed relief, relief pattern or surface portion is formed into one or more recessed lines preferably having a line width between about 500 μm and about 1,500 μm, between about 800 μm and about 1,300 μm, between about 900 μm and about 1,200 μm, or about 1,140 μm.

It is to be appreciated that said applying the electrically functional ink is not particularly limited and may be practiced with, but not limited to, a roller, a flat stamp or others. In one embodiment, said applying the electrically functional ink comprises applying the electrically functional ink generally along the plane with a generally cylindrical roller, wherein the recessed relief, relief pattern or surface portion is distanced from a contact plane of the roller, thereby reducing or preventing contact between the roller and the recessed relief, relief pattern or surface portion. In one embodiment, said applying the electrically functional ink comprises feeding the substrate between generally cylindrical ink and pressure rollers arranged generally parallel to each other, whereby the electrically functional ink is applied along the plane or to the substrate surface with the ink roller, wherein the recessed relief, relief pattern or surface portion is distanced from a contact plane of the ink roller, thereby reducing or preventing contact between the ink roller and the recessed relief, relief pattern or surface portion. In one embodiment, the ink and pressure rollers form part of a printing press. In one embodiment, said feeding the substrate comprises feeding the substrate at a speed between about 0.1 s/cm and about 10 s/cm, between about 0.2 s/cm and about 5 s/cm, between about 0.3 s/cm and about 3 s/cm, or about 0.5 s/cm. In one embodiment, the roller or ink roller is substantially cylindrical and/or has a substantially smooth sidewall without any pattern thereon.

It is to be appreciated that the electrically functional ink is not particularly limited, provided the ink permits intended operation in the printed electronic device. In one embodiment, the electrically functional ink comprises an organic semiconductor ink, a two-dimensional nanomaterial ink, a metal nanoparticle ink, a nanowire ink, a conducting polymer ink, a printable dielectric material or a solid polymer electrolyte. In one embodiment, the organic semiconductor ink comprises one or both of a molecular material and a polymer, wherein the molecular material preferably comprises a soluble derivative of pentacene or a soluble pentacene precursor molecule, and/or wherein the polymer preferably comprises polythiophene (such as poly(3-hexylthiophene) (P3HT)), polyphenylenevinylene (such as poly(p-phenylene vinylene)) or a copolymer of alternating donor and acceptor units. In one embodiment, the two-dimensional nanomaterial ink comprises an MXene ink comprising an element from one of groups 13 to 16 of the periodic table, black phosphorus, hexagonal-boron nitride or a transition-metal dichalcogenide. In one embodiment, the metal nanoparticle ink comprises silver, copper or gold nanoparticle. In one embodiment, the nanowire ink comprises a metallic nanowire (preferably comprising silver or copper) or a semiconducting nanowire. In one embodiment, the conducting polymer ink comprises polyacetylene, polyphenylene, polyazulene, polynaphthalene, poly(p-phenylene vinylene), polypyrrole, polycarbazole, polyindole, polyazepine, polyaniline, polythiophene, PEDOT or poly(p-phenylene sulfide). In one embodiment, the printable dielectric material comprises poly(vinyl phenol), polystyrene, polyimide, polyester, polymethylmethacrylate, polyvinylalcohol, poly(vinyl pyrrolidone). In one embodiment, the electrically functional ink comprises poly(3,4-ethylenedioxitiophene), poly(3,4-ethylenedioxythiophene) polystyrene sulfonate (PEDOT:PSS), poly(aniline) (PANI), poly(3-hexylthiophene) (P3HT), poly(9,9 ′-dioctyl-fluorene-co-bithiophene) (F8T2), polypyrrol, silver, gold, carbon, carbon black, graphite, graphene, graphene oxide, reduced graphene oxide or carbon nanotube. In one embodiment, the electrically functional ink comprises silver, carbon black or PEDOT:PSS. In one embodiment, the electrically functional ink comprises a water-based silver.

In one embodiment, the method comprises said applying the electrically functional ink between one and six times, between two and four times, two or three times, or two times. In one embodiment, the recessed relief pattern or surface portion is arranged to provide one or more electrically functional or conductive lines formed with the electrically functional ink in the printed electronic device, each said line having a width between about 50 μm and about 1,500 μm, between about 60 μm and about 1,000 μm, between about 70 μm and about 500 μm, between about 80 μm and about 200 μm, or about 100 μm. In one embodiment, the width is between about 100 μm and about 1,000 μm. In one embodiment, the electrically functional ink is selected to operate as a conductor, a semiconductor, a dielectric or an insulator.

In one embodiment, the printed electronic device comprises an ultra-high frequency radio frequency identification (UHF RFID) tag or a proximity sensor.

### BRIEF DESCRIPTION OF THE DRAWINGS

Reference may now be had to the following detailed description taken together with the accompanying drawings in which:

FIG. 1 shows a debossed contact printing process in accordance with a preferred embodiment of the invention;

FIG. 2 shows images of paper and debossed paper used in the process in accordance with a preferred embodiment of the invention, where top two rows show SEM images of (a, b) the watercolor paper substrate and (c, d) debossed region of watercolor paper; third row show (e) photograph and (f) optical micrograph profile of a 100-μm-deep debossed line; and the bottom row shows photographs of (g) silver, (h) carbon black, and (i) PEDOT:PSS inks printed by DCP on debossed paper;

FIG. 3 shows SEM and EDS analysis of paper composition, with top showing (a) SEM image of wood vessels at the paper surface; the middle (b) EDS elemental mapping of Ca, O, and C; and bottom (c) spectrum showing elemental composition;

FIG. 4 shows compatibility of various debossing depths with DCP, with top showing (a) optical microscope images of cross sections of paper after debossing using different pressures (top) and number of passes (left); bottom left (b) photograph of an array of squares debossed with different pressures and number of passes; and bottom right (c) photograph of DCP printed silver ink on an array of squares debossed with different pressures and number of passes;

FIG. 5 shows durability of debossed pattern to high pressure, with photographs of a spiral pattern debossed in paper (a) before and (b) after a ˜14.8 MPa pressure is applied;

FIG. 6 shows a photograph of the printing press used in accordance with a preferred embodiment of the invention, with the inset showing a side view of the rollers, and blue arrows indicating rotation direction and red arrow printing direction;

FIG. 7 shows SEM images of printed inks on watercolor paper, or namely, surfaces of printed (a-c) silver, (d-f) carbon black, and (g-i) PEDOT:PSS inks on paper after 1-3 coats;

FIG. 8 shows optical microscope images in (a-c) bright field (top) and (d-f) dark field (bottom) of silver ink printed on paper after (a,d) 1 coat, (b,e) 2 coats, and (c, f) 3 coats;

FIG. 9 shows optical microscope images in (a-c) bright field (top) and (d-f) dark field (bottom) of carbon black ink printed on paper after (a,d) 1 coat, (b,e) 2 coats, and (c, f) 3 coats;

FIG. 10 shows optical microscope images in (a-c) bright field (top) and (d-f) dark field (bottom) of PEDOT:PSS ink printed on paper after (a,d) 1 coat, (b,e) 2 coats, and (c, f) 3 coats;

FIG. 11 shows photograph of the water-based silver, carbon black, and PEDOT:PSS inks on watercolor paper;

FIG. 12 shows influence of debossed edge on wicking of a 50 mg/mL black pigment in anhydrous ethanol, with photographs, on top, of the pigment dropcast (a) on the original paper surface and (b) adjacent to a debossed line, and optical micrographs, on bottom, of the (c) free edge and (d) debossed edge of the dried spot;

FIG. 13 shows edge characterization of lines printed using DCP, with top showing optical microscope images of printed (a) silver, (b) carbon black, and (c) PEDOT:PSS line edges parallel (top) and perpendicular (bottom) to the printing direction; middle SEM images of printed (d) silver, (e) carbon black, and (f) PEDOT:PSS line edges parallel (top) and perpendicular (bottom) to the printing direction; and bottom plots of RMS line edge roughness of printed (g) silver, (h) carbon black, and (i) PEDOT:PSS inks on paper after 1-3 coats, where arrows indicate printing direction, and dotted lines are included to aid visualization of line edges in SEM images;

FIG. 14 shows, on top, optical microscope images of printed silver, carbon black, and PEDOT:PSS line edges parallel and perpendicular to the printing direction after 1-3 coats on paper, where arrows indicate printing direction; and on bottom (b) image analysis of optical microscope images using ImageJ to extract RMS line edge roughness values, where scale bars represent 300 μm;

FIG. 15 shows SEM images of printed (a) silver, (b) carbon black, and (c) PEDOT:PSS line edges parallel (top) and perpendicular (bottom) to the printing direction after 1-3 coats on paper, where arrows indicate printing direction, and scale bars represent 50 μm;

FIG. 16 shows minimum feature sizes available by DCP, with the top showing schematics and optical microscope cross-sections of debossed paper where the edges of debossed lines are spaced by a (a) 100 μm gap, and (b) <100 μm gap; and the bottom (c) digital design of 2 cm long traces with 1000, 800, 500, 300, and 100 μm widths and photographs of the printed design in (d) silver, (e) carbon black, and (f) PEDOT:PSS inks after 1 coat on paper;

FIG. 17 shows grammage and sheet resistance of printed (a) silver, (b) carbon black, and (c) PEDOT:PSS inks on paper after 1-3 coats;

FIG. 18 shows photograph of 40 μL bromophenol blue indicator deposited on oxidized PET (left) and watercolor paper (right);

FIG. 19 shows demonstrations of DCP to fabricate UHF RFID tags and smart wallpaper on paper, with top showing (a) photographs of the debossed antenna pattern and the resulting printed silver UHF RFID tag; middle (b) schematic of communication between the RFID reader and the printed paper-based silver antenna, (c) photograph demonstrating read/write capability for inventory tracking and photograph showing the printed paper-based UHF RFID tag being read, where the inset is a screenshot of the correct identification of the tag being displayed in real-time, and (d) schematic of proximity detection and subsequent wireless communication to turn a lightbulb on and off; and on bottom (e) photographs of the smart wallpaper proximity sensor made from DCP printed carbon-black when no one is within proximity (left) and when someone approaches the sensor (right);

FIG. 20 shows extracting dimensions and IC from a commercial UHF RFID tag, with top showing (a) photograph of a commercial UHF RFID tag; middle (b) dimensions of antenna accounting for debossed line width; bottom left (c) optical microscope image of Impinj Monza R6P IC on commercial antenna; and bottom right (d) optical microscope image of the cut-out IC cold-soldered on the paper-based printed silver antenna; and

FIG. 21 shows sparkfun simultaneous UHF RFID tag reader with integrated antenna and attached serial breakout.

### DETAILED DESCRIPTION OF THE PREFERRED EMBODIMENTS

In a preferred non-limiting embodiment, there is provided a patterning method for a printed paper electronic, which may affect the porous structure of paper. The applicant has appreciated that the method may permit a patterned relief structure in the paper by compressing the porous structure with a debossing tip, followed by selectively printing functional inks with a roller on the raised regions of the relief structure.

In a preferred non-limiting embodiment, there is provided a resist-free method for printing paper-based printed electronics, which may not necessarily require additional planarizing layers to improve the printability of the paper. The applicant has appreciated that the method may affect compressibility of the porous paper structure to create a relief pattern a debossing tip is used to apply pressure to selected regions of the paper. This compression may collapse the pore structure and indents these regions. The raised portions of the relief structure may contact an unpatterned printing roller, which transfers a functional ink selectively to these areas.

Previously, flexography and gravure printing have been used as roller-based contact printing processes. These printing methods may provide printing resolutions of 20-75 μm, and have been applied to fabricate patterned electrodes, antennas, solar cells, light emissive displays, and transistors. The method of the present invention, which may be referred hereinafter as a debossed contact printing (DCP) method, may be distinguishable from flexography and gravure with respect to the formation and location of the relief pattern. Whereas flexography and gravure printing both use patterned rollers to transfer the ink pattern, the method may involve debossing to imprint the pattern into the substrate.

In this regard, it has been appreciated that debossing and embossing are both embellishment techniques for graphics printing. Specifically, debossing involves pressing a pattern into the paper surface without altering the reverse side of the paper, whereas embossing involves creating a raised relief on the paper surface, with an identical and opposite imprint on the reverse side of the paper. Debossed and embossed patterns have been created using patterned plates, rollers, or serially by applying pressure to a motorized tip. Beyond graphics printing, embossing/debossing has been applied to open-channel microfluidic device fabrication to create micron-scale trenches in paper, plastic, or ceramic substrates that contain the laminar flow of liquids. Previous efforts to effect liquid containment within the trenches may be distinguished from using raised relief to receive ink in printed electronics. The applicant has appreciated that DCP on hydrophobic watercolor paper may permit a more effective process for printed electronics fabrication using water-based inks, as well as a simpler process to apply multiple coats of ink without necessarily requiring additional pattern registration steps during printing. DCP may allow suitable applications in the fabrication of devices with dense electronic features, such as antennas and patterned electrodes for RFID and smart wallpaper applications, respectively.

### Results and Discussion

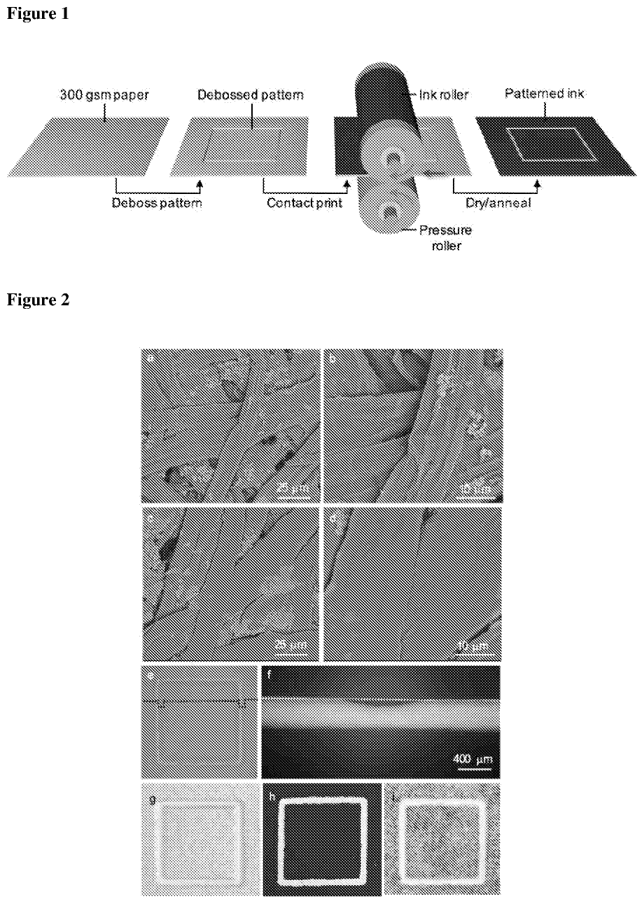

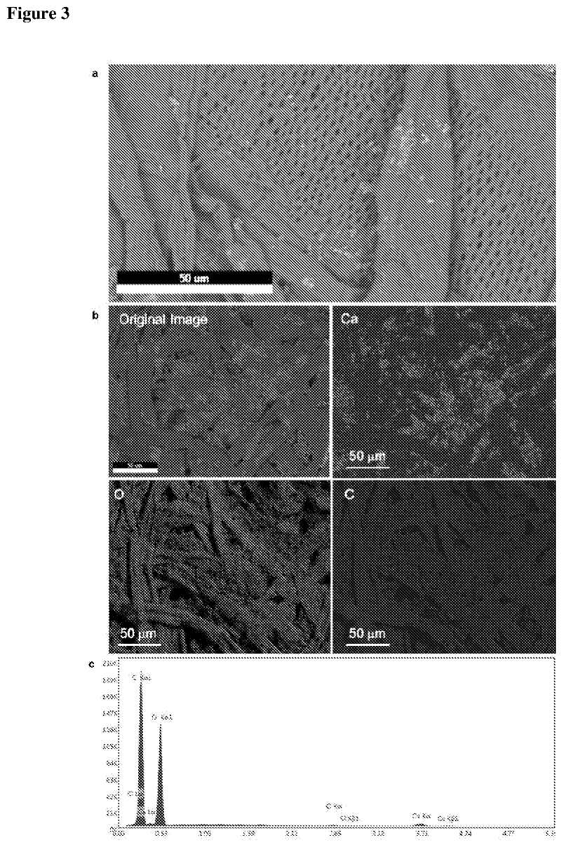

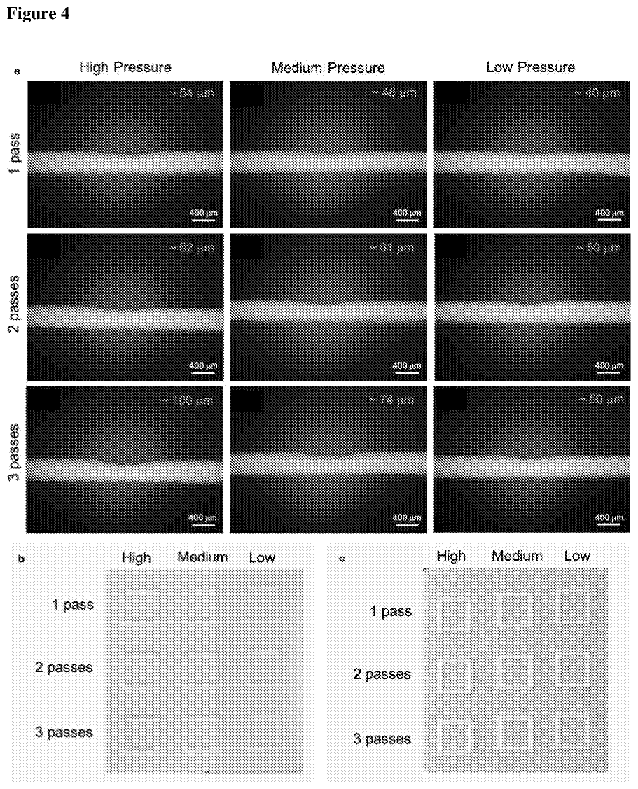

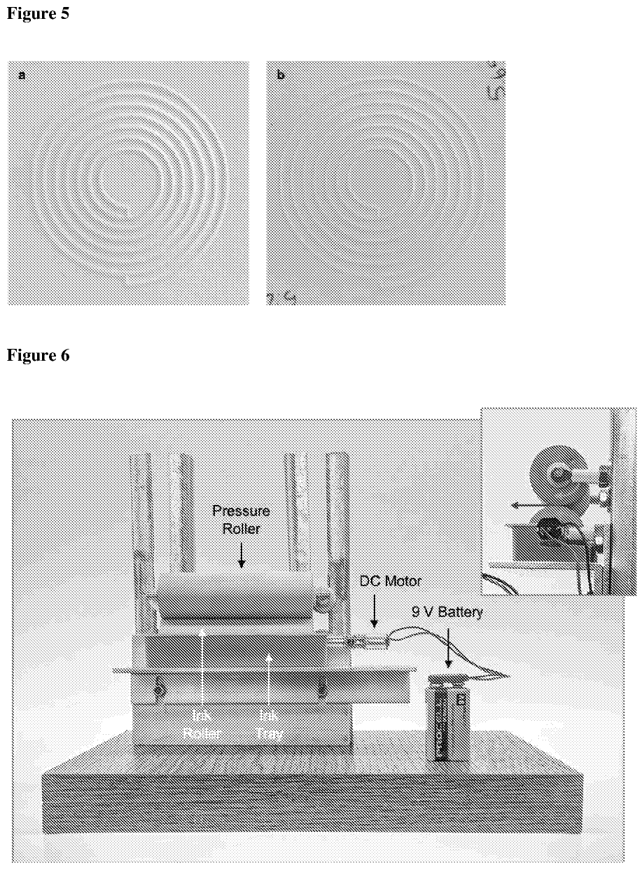

As seen in FIG. 1, in a preferred non-limiting embodiment, there is provided a DCP process, which includes serially debossing watercolor paper to create a relief pattern, followed by the application of functional inks to the raised portions of the relief structure using an unpatterned roller. A watercolor paper with a thickness of 450 μm and grammage (GSM) of 300 g/m² was used. As seen in FIGS. 2 (a, b) and 3, scanning electron microscope (SEM) and energy dispersive x-ray spectroscopy (EDS) reveal the texture and composition of the watercolor paper substrate. The paper is composed of nonwoven, entangled fibers with texture on each individual fiber (see FIG. 2 (a, b)), and the presence of some wood vessels (see FIG. 3 (a)), which is consistent with the texture of wood pulp papers. The surface is also scattered with clusters of calcium-based deposits (see FIG. 2 (a, b) and FIG. 3 (b, c)), which are likely from calcium carbonate CaCO3, a common mineral filler that improves the smoothness and ink absorbency of the paper. As seen in FIG. 1, a mechanical tip was used to create the debossed relief pattern. As seen in FIG. 2 (c, d), debossing applied pressure to the paper surface, compressing the paper by collapsing the pore structure between fibers, and smoothing individual fiber and mineral texture at the surface. Debossed features were fabricated with depths ranging from 40-100 μm by adjusting the pressure of the tip and number of debos sing iterations (see FIG. 4 (a)). The relief structure of debossed paper persisted even after a pressure of ˜14.8 MPa was applied over the entire substrate, making it compatible with pressures typically applied in R2R printing presses (<2 MPa) (see FIG. 5).

The debossed paper substrate was fed through a home-made printing press (see FIG. 6), in which a roller homogeneously coated with ink transfers the ink only to the raised regions of the relief pattern of the paper. The debossed impressions in the paper were below the contact plane of the roller, and therefore, did not pick up ink. As seen in FIG. 4 (b, c), debossing depths ranging from 40-100 μm were tested in the DCP process, all of which were sufficient to pattern the ink. A 100 μm debossing depth was used for the macro-scale patterns used hereinafter. With the mechanical tip used, the width of the debossed line was μ1140 μm (see FIG. 2 (e, f)).

As seen in FIG. 2 (g, h, i), DCP was performed by printing water-based silver, carbon black, and PEDOT:PSS conductive inks on debossed paper. Water-based silver inks have been used in printed electronics for applications where high conductivity is desirable, such as printed antennas. Recent analysis of the recyclability of paper-based electronics concluded that silver inks would not significantly impact the quality of recycled paper because of the small quantity of functional material deposited relative to the much larger weight of the paper substrate. Carbon black and PEDOT:PSS inks have also been used in printed electronics. It has been recognized that compared to other carbon-based inks, such as graphene nanoparticles and graphite, the morphology of carbon black particles may yield more uniform films with lower resistivity at low loadings. Printed carbon black films have been used as electrodes, as well as motion and proximity sensors. The conducting polymer

PEDOT:PSS has been used for biodegradable printed electronics. PEDOT:PSS layers have been printed in transistors, solar cells, and light-emissive devices.

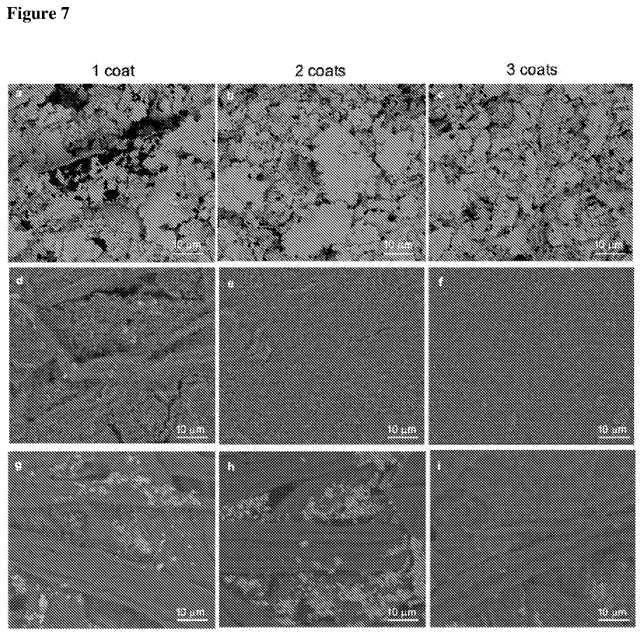

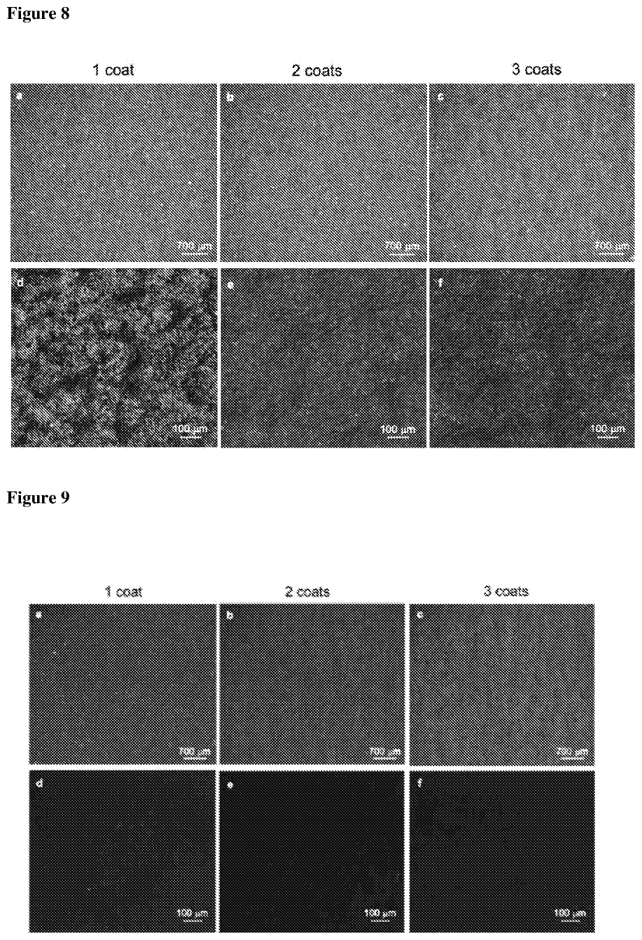

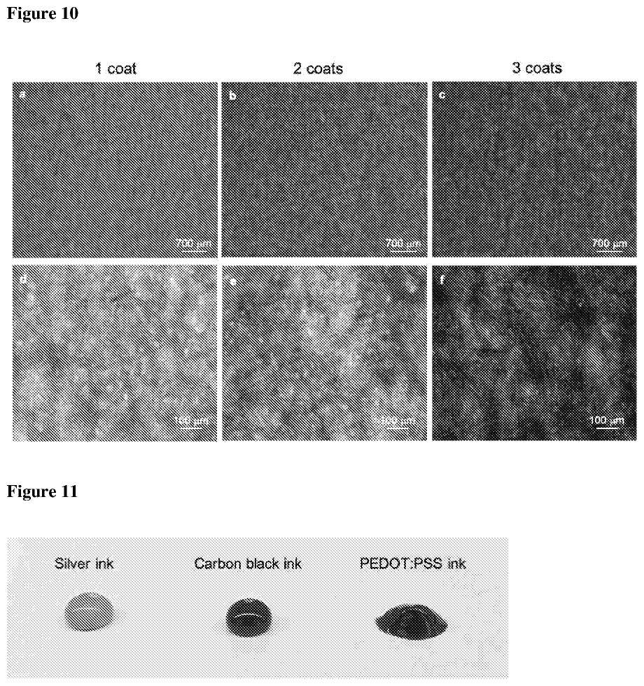

The applicant has appreciated that printing multiple coats of ink using debossed paper substrates in DCP may be more straightforward, compared to, for example, other rotary printing methods, as the paper itself may carry the patterning relief, not necessarily requiring alignment of the patterns of each coat. Uniformity, texture, and paper fiber coverage after multiple coats of the silver, carbon black, and PEDOT:PSS inks were characterized using SEM (see FIG. 7) and optical microscope images (see FIGS. 8 to 10). In one experiment, it was seen that two coats improved the coverage of the printed films, while viscous fingering is evident after printing a third coat (see FIG. 7 (g, h, i), FIG. 8 (c, f), FIG. 9 (c, f) and FIG. 10 (c, f)). Viscous fingering was ribbing along in the printing direction possibly as a result of instability at the ink-air interface as the ink separates from the elastic roller during transfer to the paper. With silver and carbon black inks, paper fibers protrude out of the printed film after one coat (see FIG. 7 (a, d)), and a second coat covers the paper fibers to provide uniform coverage (see FIG. 7 (b, e)). The printed PEDOT:PSS film did not give an obvious textural identifier, but the decreasing visibility of the calcium deposits on the paper surface may act as an indicator of surface coverage. SEM images of the printed PEDOT:PSS film after 1 and 2 coats show poor coverage of the paper fibers (see FIG. 7 (g, h)). While a third coat gave a more planarizing layer, paper fibers still protruded through the printed film (see FIG. 7 (i)).

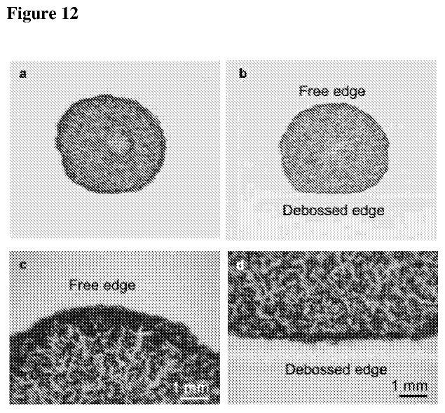

As seen in FIG. 2 (g, h, i), DCP deposited functional inks on only the raised regions of debossed paper. The interactions between the ink and paper determine the quality of the edges of printed films along the debossed trenches. The surface of the watercolor paper is hydrophobic, with a water contact angle of 124±3°. Watercolor paper formulations may include hydrophobic sizing, such as gelatin, alkyl ketene dimer, and alkenyl succinic acid anhydrate to reduce water absorbency. As seen in FIG. 11, this property of watercolor paper also inhibited the imbibition and wicking of the water-based silver, carbon black, and PEDOT:PSS functional inks. The collapsed pore structure of debossed lines may also play a role in inhibiting the wicking of inks. This effect was seen by dropcasting solutions of a black pigment in ethanol adjacent to a debossed line (see FIG. 12). Pigmented ink was used because it readily imbibes and wicks on the watercolor paper. While pigmented ink spreads easily on the paper to form a drop shape, the spreading was halted by the debossed line, resulting in the formation of a flat edge.

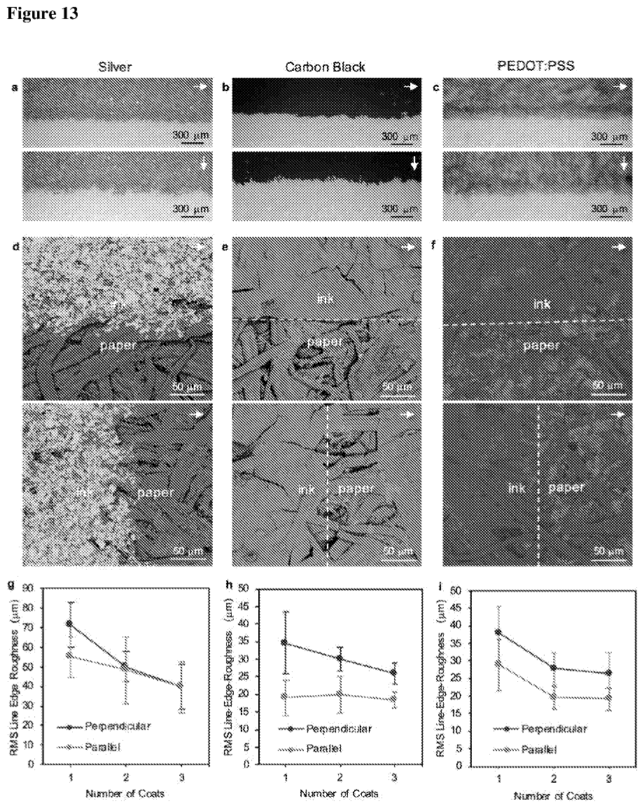

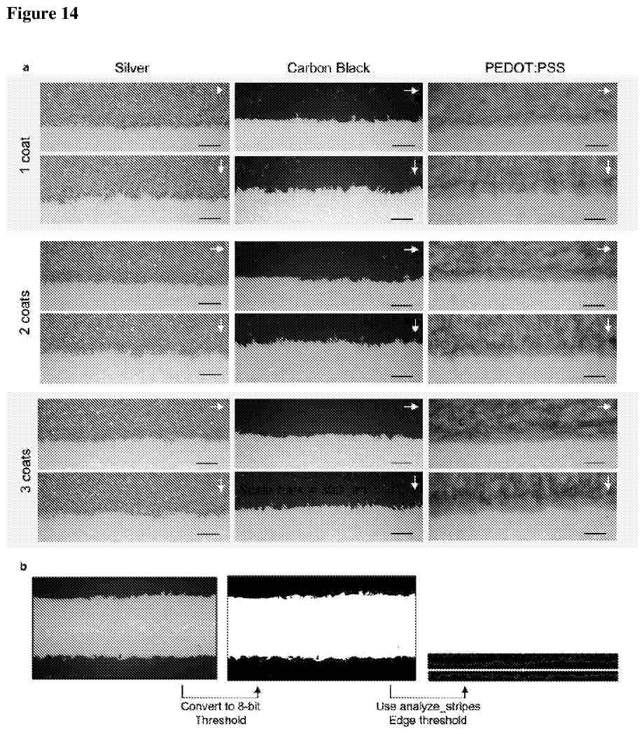

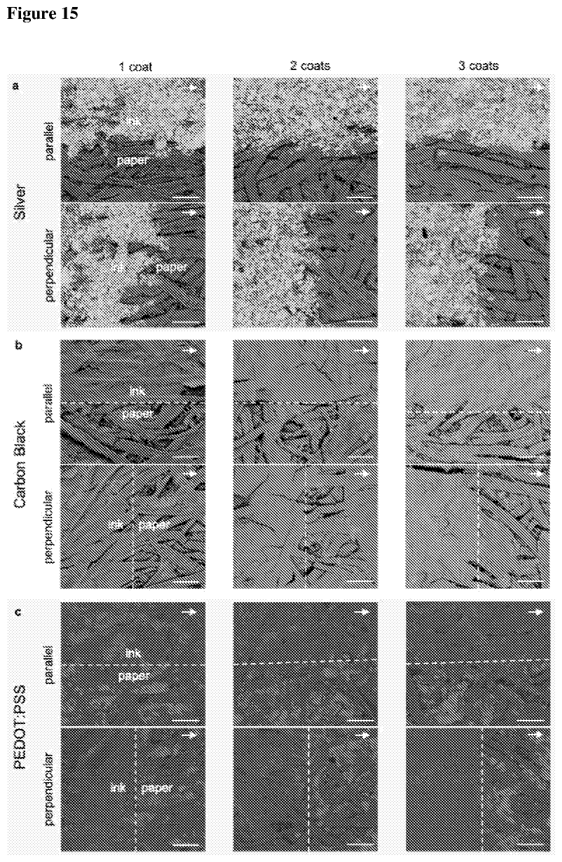

Roughness of printed line edges for the three functional inks was characterized using optical microscopy and SEM. As seen in FIGS. 13 (a-f), 14 and 15, these images revealed rough line edges parallel and perpendicular to the printing direction. The roughness of printed edges parallel and perpendicular to the printing direction was quantified by analyzing optical microscope images to calculate root-mean-square (RMS) line edge roughness (LER) values. As seen in FIG. 13 (g, h, i), this analysis showed the LER values are slightly higher for the edge perpendicular to the printing direction compared to the parallel edge. This effect may be due to breaking of the meniscus at the perpendicular edge, anisotropy in the fibers of the paper substrate itself, and/or anisotropic viscous fingering. RMS LER values decreased as additional coats of each ink are layered, which may be attributed to planarization provided by the initial coats of ink.

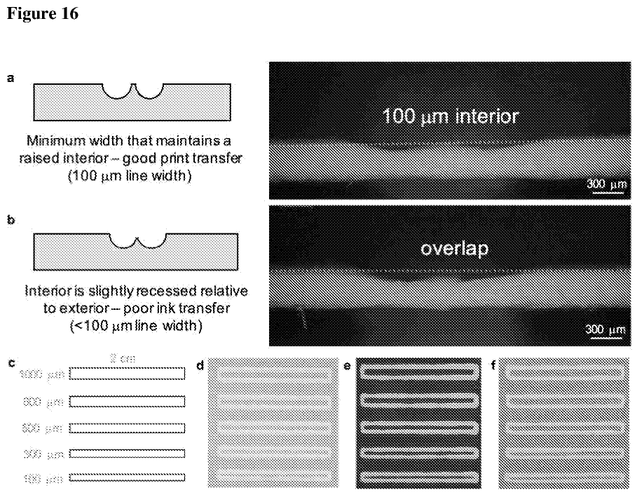

As seen in FIG. 16, the DCP process may permit fabrication of printed conductive line widths as small as 100 μm. This width matched the minimum distance between the edges of two 100-μm-deep debossed lines that may be fabricated while maintaining the relief structure (see FIG. 16 (a)). Debossing closer lines resulted in a slightly recessed paper interior in between the debossed lines (see Figure (b)), which removes this region from the contact plane with the printing roller and thus prevents ink transfer. Conductive line patterns in widths ranging from 1000-100 μm were created (see FIG. 16 (c)) using the three functional inks (see FIG. 16 (d, e, f)). Overall, the printing resolution of DCP was comparable to that of screen printing. It has been envisioned that the resolution of DCP may be improved with a debossing tip of a smaller diameter or alternative debossing methods, such as roll-to-roll or roll-to-plate debossing.

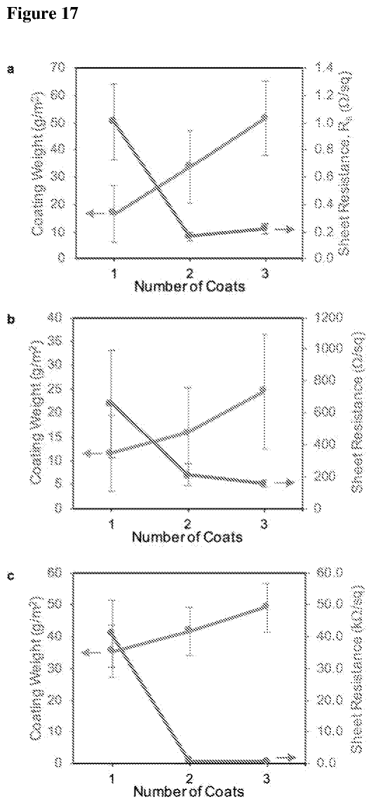

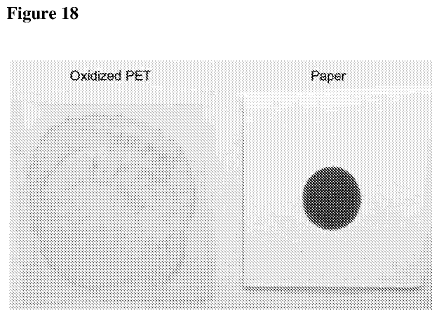

Conductivity of printed functional inks was characterized by measuring GSM and sheet resistance (R s) values after 1-3 coats of ink. As seen in FIG. 17, for all inks, printing a second coat of ink reduced the sheet resistances of the films, while a third coat adds mass but is not electrically beneficial. Table 1 below provides the GSM and R s values of the three inks and compares these values with those of a film deposited by Meyer rod coating or stencil printing on PET. A single coat of the silver and carbon black inks on paper had sheet resistance values that are higher than films of the same GSM stencil-printed on PET. Higher sheet resistances may be attributed to the inconsistent coverage of one coat of these inks on paper. Two coats of these inks on paper provided sheet resistance values comparable to those of a single coat on PET. However, even after three coats the sheet resistance of the PEDOT:PSS ink on paper was an order of magnitude higher than the sheet resistance of this ink on PET. This finding may be consistent with previous reports of printed PEDOT:PSS sheet resistance values being significantly higher (50 to 1000 times higher) on paper than on PET due to ink absorption into the paper substrate, as well as partial loss of chemical doping due to the alkalinity of paper. PEDOT:PSS conductivity may be strongly influenced by pH: high alkalinity neutralizes the acidic PSS, leading to a loss of crystallinity. As seen in FIG. 18, pH testing using bromophenol blue on our paper and oxidized PET substrates showed the high alkalinity of the paper substrate (pH>4.6) compared to PET (pH<3), which may contribute to the higher sheet resistance of PEDOT:PSS on paper even after three coats.

TABLE 1
GSM and sheet resistance values for silver flake, carbon black,
and PEDOT:PSS inks printed on debossed paper and PET.

| | Paper | | | | | | PET | |
|---|---|---|---|---|---|---|---|---|
| | 1 coat | | 2 coats | | 3 coats | | 1 coat | |
| Ink | GSM | Rₛ (Ω/sq) | GSM | Rₛ (Ω/sq) | GSM | Rₛ (Ω/sq) | GSM | Rₛ (Ω/sq) |
| Silver | 20 ± 10 | 1.0 ± 0.3 | 30 ± 10 | 0.16 ± 0.03 | 50 ± 10 | 0.22 ± 0.04 | 20 ± 10 | 0.37 ± 0.04 |
| Carbon black | 12 ± 8 | 700 ± 300 | 16 ± 9 | 210 ± 70 | 20 ± 10 | 160 ± 30 | 15 ± 9 | 400 ± 200 |
| PEDOT:PSS | 35 ± 8 | 40000 ± 10000 | 42 ± 8 | 10000 ± 2000 | 49 ± 8 | 800 ± 90 | 30 ± 10 | 16 ± 4 |

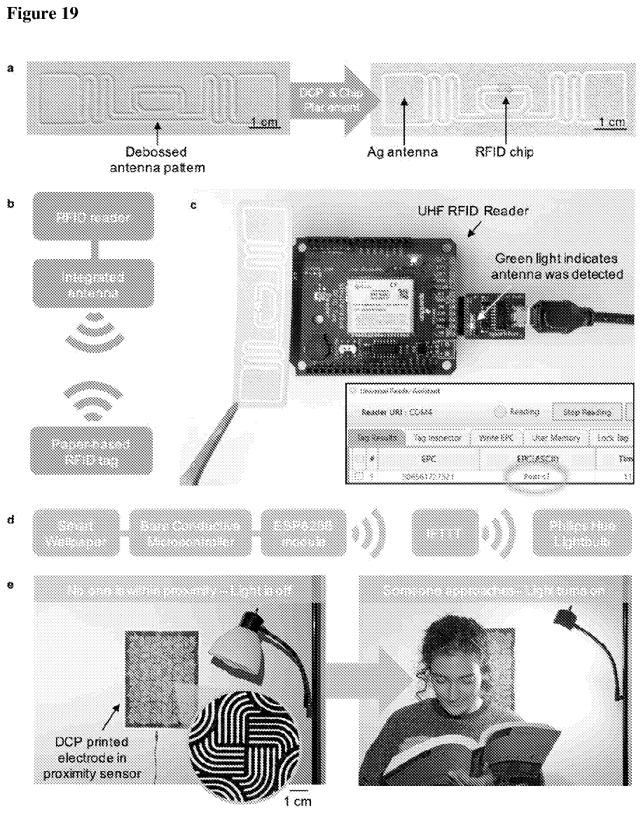

It has been recognized there may be no single printing technique that is suitable for every printed electronic device. The choice of printing technique may be influenced by ink properties, batch quantity, cost, resolution requirements, and device design. It has been envisioned that DCP may provide a less expensive printing method with more design flexibility for low-throughput prototyping. Since debossing creates the pattern, it may permit a simpler process to deboss different designs on substrates of different sizes, and then print using, for example, hand-held brayers or small-scale printing presses, such as that seen in FIG. 6. DCP may thus permit reduced complexity and cost, where compared to, for example, flexography and gravure, requiring fabrication of different patterned rollers. DCP may permit suitable applications in printing dense, single-layered electronic features, such as antennas for power or data transfer and patterned electrodes for sensors and interactive interfaces. As seen in FIG. 19, these features of DCP were illustrated by printing two devices: ultrahigh frequency radio frequency identification (UHF RFID) tags for inventory tracking, and large-area patterned electrodes for smart wallpapers.

Radio frequency identification (RFID) technology has been used for automated object identification and for different applications, such as tracking marathon runners during races, regulating access to restricted spaces, and inventory tracking. RFID tags may include a rigid integrated circuit (IC) and an impedance-matched printed antenna. Because of the rigid IC element, these tags have been manufactured by hybrid printing methods, where the antenna is first printed and then the IC is pick-and-placed on the printed antenna. For read ranges over a few meters, such as those which may be required for inventory tracking, the operating frequency of the antenna must be in the ultra-high frequency (UHF) range (902-928 MHz in North America, as defined by the EPC Gen2 standard). The antenna dimensions for UHF RFID systems should be about one-sixth of the working wavelength, which is 5-15 cm. This macroscale size may render DCP more suitable for preparing UHF RFID tags.

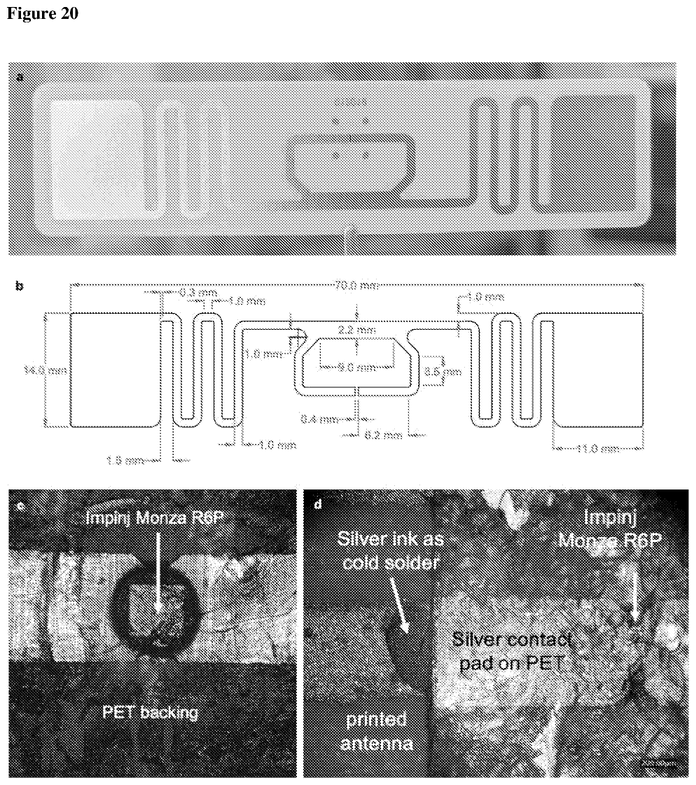

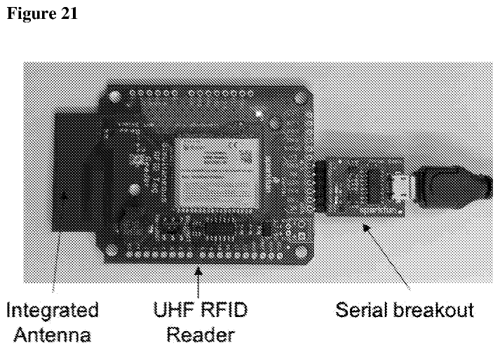

Passive UHF RFID tags were prepared using DCP to print the silver antenna. The dimensions of the printed antenna were matched to those of a commercial UHF RFID tag (see FIG. 20 (a, b)), and then the IC from the commercial tag was cold-soldered onto the paper-based printed silver antenna using silver ink (see FIGS. 19 (a) and 20 (c, d)). The read/write capability of the paper-based UHF RFID tags were tested using a commercial UHF RFID reader/writer (see FIG. 21). The UHF RFID tags are passive and work by harvesting the radio frequency signal from the reader. The energy is collected by the antenna and used to turn on the IC, which then backscatters its written information to the reader by modulating its impedance (see FIG. 19b). The reader/writer was used to write the name “Pears!” to the tag. As seen in FIG. 19 (c), the tags then detected and correctly read the name

In separate studies, DCP was used to fabricate a patterned carbon black electrode for use as a swatch of smart wallpaper for proximity sensing. Wallpaper is a large-area paper product available with debossed embellishments. Wallpaper was modified to accommodate functionality, such as proximity sensing for IoT integration. Proximity sensing is a way to ambiently detect the presence of a user without requiring intentional interaction from the user. A patterned electrode was connected to a bare conductive microcontroller, which used the patterned electrode in a self-capacitive sensor that increases in capacitance as a body approaches the electrode. The smart wallpaper swatch was integrated to the IoT. As seen in FIG. 19 (d), when an increase in capacitance is detected, a signal is sent to an online service, IFTTT, which routes a “turn on” command to a Philips Hue lightbulb. FIG. 19 (e) shows use of the smart wallpaper swatch to turn on and off a light bulb depending on the occupancy of the surrounding area.

### Conclusions

Developing scalable printing methods to fabricate paper-based printed electronics may contribute to the growth of the smart packaging market. The DCP method affects or modifies the collapsible pore structure of paper to pattern the deposition of conductive inks, thus reducing or avoiding use of additional planarization layers typically used to improve printability of paper substrates, which may reduce recyclability and/or increase the substrate cost.

The applicant has appreciated that employing debossing in DCP may permit a resist-free patterning method for printed electronics, which allows greater design flexibility for low-throughput printing. It has been envisioned that DCP may be scaled up to pattern high-throughput, large-scale paper substrates by, for example, substituting a serial debossing method with a rotary debossing method, as well as, or, increasing the length of the printing roller and printing speed. DCP may permit modifications to incorporate nonfunctional support structures in embodiments where it may be desirable to accommodate larger recessed areas and reduce unwanted contact with an inked roller.

### Experimental

The paper used is a 300 GSM watercolor paper obtained from Artist's Loft (Irving, TX). The non-volatile organic content (VOC) silver ink was obtained from SPI supplies (West Chester, PA) and used as received. The carbon black ink was obtained from Bare Conductive (London, England) and diluted with 200 mL distilled water per gram of ink. The PEDOT:PSS ink and bromophenol blue sodium salt were obtained from Sigma-Aldrich and used as received. UHF RFID integrated chips (Monza R6-P) were extracted from commercial CCRR E62 RFID Tags from atlasRFID (Birmingham, AL).

Preparation of Debossed Paper Substrates A Cricut Maker equipped with a debossing tip was used to deboss patterns on the paper substrates. Digital designs were either prepared directly in the Cricut Design Space, or on AutoCAD and subsequently imported into the Cricut Design Space. Debossing with high, medium, and low pressure was achieved using the “heavy watercolor paper 140 lb (300 GSM),” “copy paper—32 lb (128 GSM), and “copy paper—20 lb (75 GSM)” settings, respectively, at “regular pressure” in the Cricut Design Space. Except where otherwise stated, the samples were debossed with 3 passes to create a final imprint ˜100 μm deep.
Preparation of PET Substrates PET sheets were cleaned by sonicating in acetone for 5 minutes followed by isopropyl alcohol for 5 minutes, and then water for 5 minutes. The PET was then exposed to ˜570 mTorr oxygen plasma (Harrick Plasma, PDC FMG) with an air pressure of 10 psig (flow rate 29.8 mL/min) for 10 minutes at a medium discharge setting (RF power of 10.2 W).
Debossed Contact Printing A battery operated homemade printing press was used to print ink on the debossed paper and PET substrates (FIG. 6). The printing press is equipped with two 4″ Speedball Deluxe soft-rubber brayers as the ink and pressure rollers. The substrates were oriented such that the debossed side was facing the ink roller, and then were fed between the two rollers. The substrates were automatically carried through as the rollers rotate at a speed of 0.5 s/cm. Printed silver films were subsequently annealed for 10 min at 100° C. Printed carbon-black films were left to dry at room temperature for 30 mins. Printed PEDOT:PSS films were annealed for 3 min at 130° C.
Printing and Coating on PET Substrates Silver and carbon black inks were coated on oxidized PET using Mayer rods obtained from R. D. Specialties (Kent, WA) with 20 μm and 400 μm wire diameter, respectively, and a wire spacing of 100 μm. PEDOT:PSS ink was stencil printed over a 1 cm² hole that was cut into two layers of adhesive Cricut Smart Vinyl μminated on the oxidized PET substrate.
Fabrication of UHF RFID Tags Antenna dimensions were extracted from a commercial CCRR E62 RFID Tag (Monza R6-P), and a digital line-drawing was created in AutoCAD. DCP was used to deboss and print silver antennas using the extracted dimensions, and then the IC from the commercial antenna was cut and cold soldered to the printed antenna. The IC was extracted by using a scalpel to shave off the paper and adhesive coatings from the interior PET-based tag. The IC was cut to include a small (˜2-3 mm) area of the commercial antenna foil material to use as a contact pad for attachment to the printed paper-based antenna. The non-VOC silver ink used to print the paper-based antenna pattern was also used as a cold-solder to attach the IC. A clean tweezer dipped in the silver ink was dabbed on the contact pad of the cut-out IC, and the IC was then inverted to sandwich the wet silver ink onto the printed paper-based antenna. The cold solder was then annealed for 10 min at 100° C. Antenna electronic product code (EPC) names were written and read using a Sparkfun simultaneous UHF RFID tag reader (M6E Nano) with integrated antenna, attached Sparkfun serial basic breakout (CH340G), and the Universal Reader Assistant (URA) program.
Fabrication of Smart Wallpaper Swatch The smart wallpaper swatch pattern was created in AutoCAD and debossed using the Cricut Maker. Due to the large-area of the wallpaper swatch (6″×9″), a hand-rolling method was used instead of printing with the homemade rotary printing setup, which is limited to printing up to ˜3″ wide samples. Hand-rolling was done by coating a Speedball Deluxe 4″ soft-rubber brayer in carbon-black ink, and subsequently hand-rolling the brayer over the debossed wallpaper swatch. Three coats of ink were applied over the entire 6″×9″ swatch. The patterned carbon-black electrode was left to dry for 30 minutes at room temperature. The IoT integration of the patterned carbon-black electrode as a smart wallpaper swatch to turn on a lightbulb was achieved by attaching the electrode to a Bare Conductive microcontroller equipped with a DIYmall ESP8266 Serial Wifi Module and programmed with an open source software written by Carlo Palumbo, Pascal Loose and licensed by MIT.

```
Code for Smart Wallpaper Swatch
/**********************************************************
******
Bare Conductive wireless Philips Hue lightswitch
--------------------------------------------------
esp8366_ifttt_gue.ino - touch triggered WiFi lightswitch
Bare Conductive code written by Carlo Palumbo, Pascal Loose
This work is licensed under a MIT license
https://opensource.org//licenses/MIT
Copyright (c) 2021, Bare Conductive
Permission is hereby granted, free of charge, to any person obtaining a copy
of this software and associated documentation files (the “Software”), to deal
in the Software without eviction, including limitation the rights
to use, copy, modify, merge, publish, distribute, sublicense, and/or sell
copies of the Software, and to permit persons to whom the Software is
furnished to do so, subject to the following conditions:
The above copywright notice and this permission notice shall be
included in all copies or substantial portions of the software.
THE SOFTWARE IS PROVIDED “AS IS”, WITHOUT
WARRANTY OF ANY KIND. EXPRESS OR
IMPLIED, INCLUDING BUT NOT LIMITED TO THE WARRANTIES
OF MERCHANTABILITY, FITNESS FOR A PARTICULAR PURPOSE
AND NONINFRINGEMENT. IN NO EVENT SHALL
THE AUTHORS OR COPYRIGHT HOLDERS BE LIABLE
FOR ANY CLAIM, DAMAGES OR OTHER LIABILITY,
WHETHER IN AN ACTION OF CONTRACT, TORT
OR OTHERWISE, ARISING FROM OUT OF
OR IN CONNECTION WITH THE SOFTWARE OR THE ISE OR
OTHER DEALINGS IN THE SOFTWARE.
*************************************************************
*****/
  // compiler error handling
  #include “Compiler_Errors.h”
  // touch includes
  #include <MPR121.h>
  // wifi includes
  #include “WiFiEsp.h”
  #include “AnotherIFTTTWebhook.h”
  // touch constants
  const uint32_t BAUD_RATE = 115200;
  const uint8_t MPR121_ADDR = 0x5C;
  const uint8_t MPR121_INT = 4;
  // wifi constants
  char ssid[ ] = “wifiname”; // change to your network SSID (name)
  char pass[ ] = “xxxx”; // change to your network password
  int status = WL_IDLE_STATUS; // the Wifi radio's status
  #define IFTTT_Key “bAQpkEdhirDFDIGsD3LA-d” // change to your
  IFTTT webhook
  key
  #define IFTTT_Event “toggle_lights” // change to your IFTTT event
  name
  void setup( )
  {
  // initialize serial for debugging
  Serial.begin(BAUD_RATE);
  // initialize serial for ESP module
  Serial1.begin(BAUD_RATE);
  // initialize ESP module
  WiFi.init(&Serial1);
  if (!MPR121.begin(MPR121_ADDR)) {
    Serial.println(“error setting up MPR121”);
    switch (MPR121.getError( )) {
    case NO_ERROR:
      Serial.println(“no error”);
      break;
    case ADDRESS_UNKNOWN:
      Serial.println(“incorrect address”);
      break;
    case READBACK_FAIL:
      Serial.println(“readback failure”);
      break;
    case OVERCURRENT_FLAG:
      Serial.println(“overcurrent on REXT pin”);
      break;
    case OUT_OF_RANGE:
      Serial.println(“electrode out of range”);
      break;
    case NOT_INITED:
      Serial.println(“not initialised”);
      break;
    default:
      Serial.println(“unknown error”);
      break;
    }
    while (1);
  }
  MPR121.setInterruptPin(MPR121_INT);
  MPR121.setTouchThreshold(2);
  MPR121.setReleaseThreshold(1);
  // check for the presence of the module
  if (WiFi.status( ) == WL_NO_SHIELD) {
    Serial.println(“WiFi module not present”);
    while (true);
  }
  // attempt to connect to WiFi network
  while ( status != WL_CONNECTED) {
    Serial.print(“Attempting to connect to WPA SSID: ”);
    Serial.println(ssid);
    status = WiFi.begin(ssid, pass); // connect to WPA/WPA2 network
  }
  Serial.println(“You're connected to the network”);
  printWifiStatus( );
  Serial.println( );
  Serial.println(“Starting connection to server...”);
  }
  void loop( ) {
  MPR121.updateAll( );
  if (MPR121.getNumTouches( ) <= 1) {
    if (MPR121.isNewTouch(11)) {
    Serial.println(“Sending the event to IFTTT”);
    send_webhook(IFTTT_Event, IFTTT_Key);
    }
  }
  }
  void send_webhook(char *MakerIFTTT_Event, char
  *MakerIFTTT_Key) {
  client.connect(“maker.ifttt.com”, 80); // connect to the Maker event
  server
  // construct the POST request
  char post_rqst[256]; // hand-calculated to be big enough
  char *p = post_rqst;
  p = append_str(p, “POST /trigger/”);
  p = append_str(p, MakerIFTTT_Event);
  p = append_str(p, “/with/key/”);
  p = append_str(p, MakerIFTTT_Key);
  p = append_str(p, “ HTTP/1.1\r\n”);
  p = append_str(p, “Host: maker.ifttt.com\r\n”);
  p = append_str(p, “Content-Type: application/json\r\n”);
  p = append_str(p, “Content-Length: ”);
  char *content_length_here = p; // remember where the content length
  will go
  p = append_str(p, “NN\r\n”); // it's always two digits, so reserve space
  for them (the
  NN)
  p = append_str(p, “\r\n”); // end of headers
  char *json_start = p; // construct the JSON; remember where we
  started so we will
  know len
  // go back and fill in the JSON length
  // we just know this is at most 2 digits (and need to fill in both)
  int i = strlen(json_start);
  content_length_here[0] = ‘0’ + (i / 10);
  content_length_here[1] = ‘0’ + (i % 10);
  // finally we are ready to send the POST to the server!
  client.print(post_rqst);
  client.stop( );
  }
  void printWifiStatus( ) {
  // print the SSID of the attached network
  Serial.print(“SSID: ”);
  Serial.println(WiFi.SSID( ));
  // print the WiFi module's IP address
  IPAddress ip = WiFi.localIP( );
  Serial.print(“IP Address: ”);
  Serial.println(ip);
  // print the received signal strength
  long rssi = WiFi.RSSI( );
  Serial.print(“Signal strength (RSSI):”);
  Serial.print(rssi);
  Serial.println(“ dBm”);
  }
```

Characterization Optical images were taken using an Olympus BX51 microscope and Olympus Q-Color3 digital camera. Line-edge roughness of the patterned sensor was obtained by analyzing optical microscope images using the Analyze_Stripes macro for ImageJ. The reported line-edge roughness is an average of 6 total RMS line-edge roughness values from 3 images of different samples (2 values extracted per sample). SEM images and EDS spectra were collected using a Quanta 200 FEG Environmental Scanning Electron Microscope using 12 kV, a spot size of 3, and a working distance of 9-10 mm Sheet resistances of 1 cm² samples were measured with a Keithley 2601A Sourcemeter. The reported sheet resistances are averages of at least 7 samples. The pH of paper and PET substrates were assessed by dropcasting 40 μat of a bromophenol blue indicator solution onto the substrates. The bromophenol blue indicator solution was prepared by dissolving 0.4 g of bromophenol blue sodium salt in 95% ethanol.

While the invention has been described with reference to preferred embodiments, the invention is not or intended by the applicant to be so limited. A person skilled in the art would readily recognize and incorporate various modifications, additional elements and/or different combinations of the described components consistent with the scope of the invention as described herein.

We claim:

1. A method for preparing a printed electronic device, the method comprising debos sing a recessed relief or relief pattern into a plane of a substrate, and applying an electrically functional ink generally along the plane, thereby depositing the ink on the plane of the substrate substantially without depositing the ink on the recessed relief or relief pattern.

2. The method of claim 1, wherein the substrate comprises paper, cardboard, foamboard or polymer.

3. The method of claim 1, wherein the substrate comprises watercolor paper having a thickness between about 100 μm and about 1,000 μm, a grammage between about 50 g/m² and about 700 g/m², and/or a water contact angle between about 80° and about 160°.

4. The method of claim 1, wherein the recessed relief or relief pattern is recessed to a depth between about 10 μm and about 700 μm from the plane, optionally wherein the depth is selected to reduce movement of the ink towards the recessed relief or relief pattern.

5. The method of claim 1, wherein said applying the electrically functional ink comprises feeding the substrate between generally cylindrical ink and pressure rollers arranged generally parallel to each other, whereby the electrically functional ink is applied along the plane with the ink roller, wherein the recessed relief or relief pattern is distanced from a contact plane of the ink roller, thereby reducing or preventing contact between the ink roller and the recessed relief or relief pattern.

6. The method of claim 1, wherein the electrically functional ink comprises poly(3,4-ethylenedioxitiophene), poly(3,4-ethylenedioxythiophene) polystyrene sulfonate (PEDOT:PSS), poly(aniline) (PANI), poly(3-hexylthiophene) (P3HT), poly(9,9′-dioctyl-fluorene-co-bithiophene) (F8T2), polypyrrol, silver, silver nanowire, gold, carbon, carbon black, graphite, graphene, graphene oxide, reduced graphene oxide or carbon nanotube.

7. The method of claim 1, wherein the method comprises said applying the electrically functional ink two or three times.

8. The method of claim 1, wherein the recessed relief pattern is arranged to provide one or more electrically functional or conductive lines in the printed electronic device, each said line having a width between about 100 μm and about 1,000 μm.

9. A method for preparing a printed electronic device, the method comprising providing a substrate having a generally planar substrate surface; debossing a relief or relief pattern into the substrate surface, the relief or relief pattern being recessed from the substrate surface; and applying an electrically functional ink to the substrate surface with a generally cylindrical roller, thereby depositing the ink on the substrate surface substantially without depositing the ink on the relief or relief pattern.

10. The method of claim 9, wherein the substrate comprises paper, cardboard, foamboard or polymer.

11. The method of claim 9, wherein the substrate comprises watercolor paper having a thickness between about 100 μm and about 1,000 μm, a grammage between about 50 g/m² and about 700 g/m², and/or a water contact angle between about 80° and about 160°.

12. The method of claim 9, wherein the relief or relief pattern is recessed to a depth between about 10 μm and about 700 μm from the substrate surface, optionally wherein the depth is selected to reduce movement of the ink towards the relief or relief pattern.

13. The method of claim 9, wherein the roller is an ink roller, and said applying the electrically functional ink comprises feeding the substrate between the ink roller and a generally cylindrical pressure roller arranged generally parallel to the ink roller, whereby the electrically functional ink is applied to the substrate surface with the ink roller, wherein the relief or relief pattern is distanced from a contact plane of the ink roller, thereby reducing or preventing contact between the ink roller and the relief or relief pattern.

14. The method of claim 9, wherein the electrically functional ink comprises poly(3,4-ethylenedioxitiophene), poly(3,4-ethylenedioxythiophene) polystyrene sulfonate (PEDOT:PSS), poly(aniline) (PANI), poly(3-hexylthiophene) (P3HT), poly(9,9′-dioctyl-fluorene-co-bithiophene) (F8T2), polypyrrol, silver, silver nanowire, gold, carbon, carbon black, graphite, graphene, graphene oxide, reduced graphene oxide or carbon nanotube.

15. The method of claim 9, wherein the method comprises said applying the electrically functional ink two or three times.

16. The method of claim 9, wherein the relief pattern is arranged to provide one or more electrically functional or conductive lines in the printed electronic device, each said line having a width between about 100 μm and about 1,000 μm.

17. A method for preparing a printed electronic device, the method comprising compressing a portion of a paper substrate substantially into a plane thereof to obtain a recessed surface portion and a non-recessed surface portion, and applying an electrically functional ink generally along the plane, thereby depositing the ink on the non-recessed surface portion substantially without depositing the ink on the recessed surface portion, wherein the recessed surface portion is selected to reduce movement of the ink from the non-recessed surface portion.

18. The method of claim 17, wherein the paper substrate comprises watercolor paper having a thickness between about 300 μm and about 600 μm, a grammage between about 200 g/m² and about 400 g/m², and/or a water contact angle between about 100° and about 140°.

19. The method of claim 17, wherein the recessed surface portion is recessed to a depth between about 40 μm and about 100 μm from the plane.

20. The method of claim 17, wherein said applying the electrically functional ink comprises feeding the paper substrate between generally cylindrical ink and pressure rollers arranged generally parallel to each other, whereby the electrically functional ink is applied along the plane with the ink roller, wherein the recessed surface portion is distanced from a contact plane of the ink roller, thereby reducing or preventing contact between the ink roller and the recessed surface portion.

21. The method of claim 17, wherein the electrically functional ink comprises poly(3,4-ethylenedioxitiophene), poly(3,4-ethylenedioxythiophene) polystyrene sulfonate (PEDOT:PSS), poly(aniline) (PANI), poly(3-hexylthiophene) (P3HT), poly(9,9′-dioctyl-fluorene-co-bithiophene) (F8T2), polypyrrol, silver, silver nanowire, gold, carbon, carbon black, graphite, graphene, graphene oxide, reduced graphene oxide or carbon nanotube.

22. The method of claim 17, wherein the method comprises said applying the electrically functional ink two or three times.

23. The method of claim 17, wherein said compressing the portion of the paper substrate comprises compressing two or more said portions of the paper substrate to obtain two or more said recessed surface portions and the non-recessed surface portion, said two or more recessed surface portions being arranged to provide one or more electrically functional or conductive lines in the printed electronic device, each said line having a width between about 100 μm and about 1,000 μm.
